(19) United States
(12) Patent Application Publication
(10) Pub. No.: US 2024/0353506 A1
(43) Pub. Date: Oct. 24, 2024

(54) Space Magnetometer System

(71) Applicant: THE REGENTS OF THE UNIVERSITY OF MICHIGAN, Ann Arbor, MI (US)

(72) Inventors: Leonardo REGOLI, Laurel, MD (US); Finna Hope BRONNER, Rockville, MD (US); Curt Raymond COOPER, Jackson, MI (US); Jonathan VAN NOORD, Dexter, MI (US); Lauro V. OJEDA, Ann Arbor, MI (US); Mark B. MOLDWIN, Ann Arbor, MI (US)

(21) Appl. No.: 18/636,349

(22) Filed: Apr. 16, 2024

Related U.S. Application Data
(60) Provisional application No. 63/461,372, filed on Apr. 24, 2023.

(51) Int. Cl. G01R 33/00

(52) U.S. Cl. CPC G01R 33/0047; G01R 33/0076

(57) ABSTRACT

A magnetometer system having a magneto-inductive sensor configured to provide satellite attitude determination, magnetic noise identification, and magnetic field information; electronics operably coupled to the sensor configured to protect against electrostatic discharge and measure temperature of the sensor for thermal calibration; and an aluminum chassis supporting and protecting the sensor.

### CROSS-REFERENCE TO RELATED APPLICATIONS

This application claims the benefit of U.S. Provisional Application No. 63/461,372, filed on Apr. 24, 2023. The entire disclosure of the above application is incorporated herein by reference.

### GOVERNMENT INTEREST

This invention was made with government support under 80NSSC18K1240 and 80NSSC19K0608 awarded by the National Aeronautics and Space Administration. The government has certain rights in the invention.

### FIELD

The present disclosure relates to space exploration and, more particularly, relates to a magneto-inductive magnetometer operable for attitude determination, spacecraft magnetic noise sensing, and space physics science investigations.

### BACKGROUND & SUMMARY

This section provides background information related to the present disclosure which is not necessarily prior art. This section provides a general summary of the disclosure, and is not a comprehensive disclosure of its full scope or all of its features.

Magnetic fields are ubiquitous in our solar system and of key importance for geophysical, magnetospheric and heliospheric investigations. The sun produces the interplanetary magnetic field (IMF) and many of the planets and moons throughout the solar system produce their own magnetic fields through dynamo and magneto-inductive response processes. Even where no internally produced magnetic field is present, for example, Mars or Venus, the IMF plays a major role in how planets and smaller bodies interact with the solar wind.

At Earth, the measured field is a combination of the internal dynamo-generated field and perturbations that occur in space, particularly during substorm and geomagnetic storm processes. These processes are governed by the direction of the IMF and the dynamic pressure exerted by the solar wind at any given time. The enhancement of the particle fluxes in the ring current during a geomagnetic storm causes the measured magnetic field strength at the surface of the Earth to decrease. This is quantified by the so-called disturbance storm time (Dst) index, which is determined by a network of low-latitude magnetometers.

The dynamic nature of planetary magnetospheres makes it extremely difficult, if not impossible, to understand their structure without the help of a magnetometer with sufficient resolution, dynamic range, and bandwidth, to discriminate between the different regions inside the magnetosphere and identify the magnetic signature of plasma flows that are governed by global and local circulation patterns. For this reason, magnetometers have been a key tool in magnetospheric investigations throughout the history of their study and continue to be indispensable. Critically, current and planned investigations of multi-scale dynamic features throughout the solar system continue to drive the need for greater numbers of magnetometers with state-of-the-art capabilities.

According to the principles of the present teachings, a space-qualified magnetometer system is provided having a firmware modified commercial magneto-inductive (MI) sensor (the RM3100 from PNI Sensor) that can be used for satellite attitude determination, spacecraft magnetic noise identification, and space science investigations of magnetic fields. The MI sensor of the present teachings is coupled with electronics to protect against electrostatic discharge and to measure the temperature of the sensor for thermal calibration. The MI sensor is housed within an aluminum chassis for micrometeorite and radiation protection as well as passive thermal control. The MI sensor has been tested for total ionizing dose and single event effects radiation impacts and fully qualified for space applications. The magnetometer system of the present teachings is extremely low power, low mass, and extremely radiation tolerant and can be used for scientific and commercial satellites.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 illustrates a PNI RM3100 sensor;

FIG. 2 illustrates a space-qualified magnetometer system according to the principles of the present teachings; and

FIGS. 3A and 3B illustrate the space-qualified magnetometer system according to the principles of the present teachings.

Corresponding reference numerals indicate corresponding parts throughout the several views of the drawings.

### DETAILED DESCRIPTION

Example embodiments will now be described more fully with reference to the accompanying drawings. Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

According to the principles of the present teachings, as illustrated in the attached figures, a space-qualified magnetometer system 10 is provided having a firmware modified commercial magneto-inductive (MI) sensor 12 (the RM3100 from PNI Sensor) that can be used for satellite attitude determination, spacecraft magnetic noise identification and space science investigations of magnetic fields. It should be understood that the present teachings are not limited to PNI RM3100 magnetometers per se, but can be used with alternative magnetometers or equivalents. In the interest of clarity, the RM3100 magnetometer will be referenced in the present teachings, but this should not be regarded as limiting unless specifically noted and/or claimed.

The MI sensor 12 of the present teachings is coupled with electronics 14 via a communication interface 16 to protect against electrostatic discharge and to measure the temperature of the sensor for thermal calibration. The MI sensor 12 is housed within an aluminum chassis 18 for micrometeorite and radiation protection as well as passive thermal control. In some embodiments, aluminum chassis 18 comprises a first half 20 and a second half 22 joined along an interface 24. First half 20 and second half 22 can be fixedly coupled together to contain MI sensor 12 therein. In some embodiments, first half 20 and second half 22 are joined by a plurality of fasteners 26. Aluminum chassis 18 is sized to provide the aforementioned micrometeorite and radiation protection. In some embodiments, aluminum is chosen due to its cost, machine-ability, weight, non-magnetic properties, and thermal, radiation and micrometeorite protection capabilities. However, it should be understood that alternative materials may be used.

The MI sensor 12 has been tested for total ionizing dose and single event effects radiation impacts and fully qualified for space applications. The magnetometer system 10 of the present teachings is extremely low power, low mass, and extremely radiation tolerant and can be used for scientific and commercial satellites.

In particular, the MI sensor 12, such as RM3100 magnetometer built by PNI Sensor Corporation, is based on a measurement principle significantly different from the current standards for space applications like fluxgate, helium, magneto-resistive or Hall magnetometers. The RM3100 magnetometer is intended for Earth-based applications and is particularly well suited for automotive applications such as compassing or for detection of nearby objects due to its small size. However, its performance under magnetic field conditions observed at planetary magnetospheres, makes the magneto-inductive technology a promising one for low-cost space missions based on small satellite technologies.

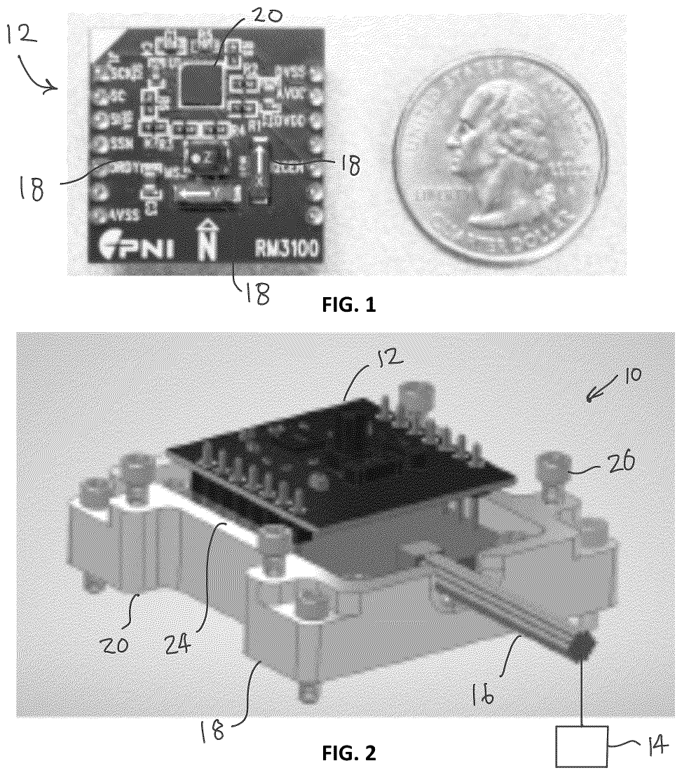

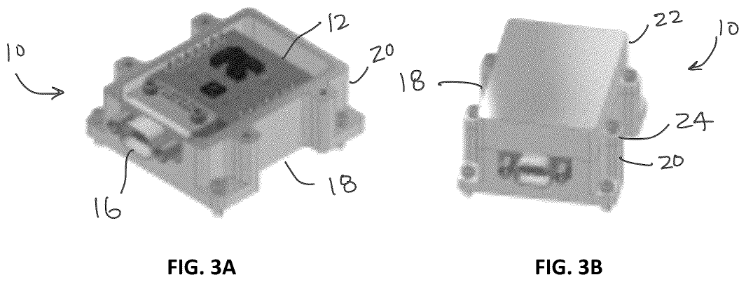

The MI sensor 12, as illustrated in FIG. 1, is based on a magneto-inductive principle. The MI sensor 12 comprises orthogonal coils 18, and an ASIC controller 20 with peripheral electronics. In order to communicate with the ASIC controller, a PNI Communication Board (CommBoard) was used. The CommBoard introduces a constant offset of up to several hundreds of nT, which is easily eliminated by removing the bias. However, this CommBoard is only used for test purposes. A dedicated electronic circuit and microcontroller have been designed for integration into a small satellite.

The sensor is a simple resistor-inductor (RL) circuit that does not use an analog to digital (A/D) converter—one of the electronic components that is sensitive to external radiation in traditional fluxgate magnetometer designs. The operating principle of the MI sensor 12 involves measurement of the time it takes to charge and discharge an inductor between an upper and lower threshold by means of a Schmitt trigger oscillator. This time is proportional to the applied field strength, within a specified operational range.

The total magnetic field that MI sensor 12 experiences is due to the external field and the field generated by the circuit (H=kI+HE, where k is a property of the coil, I is the current through the circuit and HE is the external field). The Schmitt trigger causes the current through the circuit to oscillate as the voltage across the resistor (Rb) passes a set ‘trigger’ value. As the applied current oscillates the inductance of the circuit (and hence the time constant) changes.

An applied magnetic field causes a constant offset in the coils' field strength, the polarity of which is determined by the direction of the field. This offset causes the average permeability and therefore inductance to be lower in one direction and larger in the other yielding a corresponding difference in the time required to complete the minor B-H loops in each direction. By integrating over many such minor loops in each direction, the time difference, and therefore available resolution, can be enhanced to any desired level subject to integrated noise sources.

Magneto-inductive sensing hinges on the fact that the induction of a coil wrapped around a highly permeable magnetic core will fluctuate with respect to the magnetic field being applied to the coil, and the inductance of the sensor is a function of the magnetic field.

The circuit employs a Schmitt trigger with a bias resistor (Rb) and the MI sensor in a feedback loop. It functions as an oscillator whenever a voltage is applied. The period of the circuit's oscillation varies with the inductance of the MI sensing coil and therefore the external field. When no external magnetic field is applied, driving the circuit with a positive (forward) or negative (reverse) voltage will yield the same oscillatory period. However, if there is a field present, the oscillatory period for forward biassing the circuit and reverse biassing the circuit will be different. Measuring the time to complete a cycle in both directions and taking the difference yields a value that can be directly related to the magnetic field.

The novel underlying principle of this technology, in which the magnetic field is determined solely by the time difference between forward and reverse biased cycles, provides a completely digital measurement without the use of an analog-to-digital converter (ADC) or an amplifier. These components are weak points of traditional magnetometers, and their elimination significantly decreases the power budget and failure rate of the instrument. Additionally, the simple oscillatory circuit and components that drive the technology are well-suited for mass production, lowering the cost to produce sensors significantly. These advantages are key criterion for deployment in future multi-CubeSat missions to potentially study the dynamics of planetary magnetospheres and the solar wind.

The performance of a single RM3100 magnetometer has been extensively studied previously. It should be noted that the demonstrated sampling frequency and corresponding resolution of the sensor present applicability to the study of ultra-low-frequency (ULF) magnetospheric waves in the PC4-PC5 range. With that said, a resolution improvement of at least 2× is required for deep-space missions where the magnetic field is on the order of 1-10 nT, and upwards of 20× improvement is required for the instrument to observe PC1 waves. The area, weight, and power consumption of the instrument alone, however, open the door to CubeSat missions and power-limited ground-based systems (remotely operated vehicles, planetary landers, or extreme Earth-based environments). The sensor has already been employed in both terrestrial and aeromagnetic geological surveys of iron ore deposits, demonstrating the applicability of the RM3100 to geomagnetic, space physics, or other magnetometer application.

Beyond the baseline features, a surprising but nonetheless valuable additional characteristic of the RM3100 is its relative radiation hardness. It should also be noted that an appreciable difference in resolution was not observed in comparing pre- and post-irradiation measurements for working magnetometers. Being robust up to 150 krad (SI) enables its use in a variety of space environments including potential missions to the Jovian moons or Van Allen radiation belts where TID is expected to be high for typical mission lengths. In addition, tests for destructive single-event effect susceptibility of the PNI RM3100 magnetometer sensor were conducted using the heavy ion beam at the Lawrence Berkeley National Laboratory's Cyclotron. The tests found no single event latch-up events for LET>75 MeVcm² mg⁻¹ at an elevated temperature of 85 C.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. A magnetometer system comprising:
a magneto-inductive sensor configured to provide satellite attitude determination, magnetic noise identification, and magnetic field information;
electronics operably coupled to the magneto-inductive sensor configured to protect against electrostatic discharge and measure temperature of the sensor for thermal calibration; and
an aluminum chassis supporting and protecting the magneto-inductive sensor.

2. The magnetometer system according to claim 1 wherein the aluminum chassis comprises a first half and second half connectable along an interface, the magneto-inductive sensor being contained within the aluminum chassis.

3. The magnetometer system according to claim 2 further comprising a plurality of fasteners coupling the first half to the second half.

4. The magnetometer system according to claim 1 wherein the aluminum chassis is configured to protect the magneto-inductive sensor from radiation.

5. The magnetometer system according to claim 1 wherein the aluminum chassis is configured to protect the magneto-inductive sensor from micrometeorites.
